(19) United States
(12) Patent Application Publication
(10) Pub. No.: US 2025/0329662 A1
(43) Pub. Date: Oct. 23, 2025

(54) Semiconductor Device and Method of Forming Stacked SIP Structure with Single-Sided Mold

(71) Applicant: JCET STATS ChipPAC Korea Limited, Incheon (KR)

(72) Inventors: SeungHyun Lee, Incheon (KR); Yeojun Yun, Incheon (KR); HeeSoo Lee, Incheon (KR)

(73) Assignee: JCET STATS ChipPAC Korea Limited, Incheon (KR)

(21) Appl. No.: 18/637,657

(22) Filed: Apr. 17, 2024

(51) Int. Cl. H01L 23/552; H01L 21/56; H01L 23/00; H01L 23/31; H01L 23/498; H01L 25/16

(52) U.S. Cl. CPC H01L 23/552; H01L 21/56; H01L 23/3128; H01L 23/49816; H01L 24/16; H01L 24/29; H01L 24/32; H01L 24/73; H01L 25/165; H01L 2224/16227; H01L 2224/2919; H01L 2224/32225; H01L 2224/73253

(57) ABSTRACT

A semiconductor device has a first substrate and a plurality of first electrical components disposed over a first surface of the first substrate. A second substrate has a plurality of second electrical components. The second substrate is disposed over at least one of the first electrical components. A first encapsulant is deposited over the first substrate, first electrical components, second substrate, and second electrical components. A first shielding material is disposed over the first encapsulant. A second encapsulant can be deposited over the second substrate and second electrical components. A second shielding material can be disposed over the second encapsulant. An adhesive or plurality of bumps can be disposed between the second substrate and the at least one of the first electrical components. An epoxy material can be disposed between the second substrate and the at least one of the first electrical components.

### FIELD OF THE INVENTION

The present invention relates in general to semiconductor devices and, more particularly, to a semiconductor device and method of forming a stacked SiP structure having a single-sided mold.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Multiple semiconductor die and IPDs can be integrated into a system-in-package (SiP) module for higher density in a small space and extended electrical functionality. Within the SiP module, a plurality of first semiconductor die and IPDs are disposed on a first surface of a substrate for structural support and electrical interconnect. A first encapsulant is deposited over the first semiconductor die and IPDs on the first surface of the substrate. A plurality of second semiconductor die and IPDs is disposed on a second surface of the substrate opposite the first surface of the substrate for structural support and electrical interconnect. A second encapsulant is deposited over the second semiconductor die and IPDs on the second surface of the substrate. The first electrical components and IPDs disposed on the first surface of the substrate and second electrical components and IPDs disposed on the second surface of the substrate provide higher density in a small space and extended electrical functionality for the SiP module. However, the deposition of the first encapsulant on the first semiconductor die and IPDs on the first surface of the substrate and deposition of the second encapsulant on the second semiconductor die and IPDs on the second surface of the substrate, known as double-side mold (DSM), adds time and cost to the manufacturing process.

### BRIEF DESCRIPTION OF THE DRAWINGS

FIGS. 1a-1c illustrate a semiconductor wafer with a plurality of semiconductor die separated by a saw street;

FIGS. 2a-2j illustrate a process of forming a stacked SiP structure having single-sided mold;

FIGS. 3a-3g illustrate another process of forming a stacked SiP structure having single-sided mold;

FIGS. 4a-4d illustrate a process of forming a shielded SiP module;

FIGS. 5a-5d illustrate a process of forming a stacked SiP structure having single-sided mold and using the shielded SiP module from FIGS. 4a-4d; and

FIG. 6 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

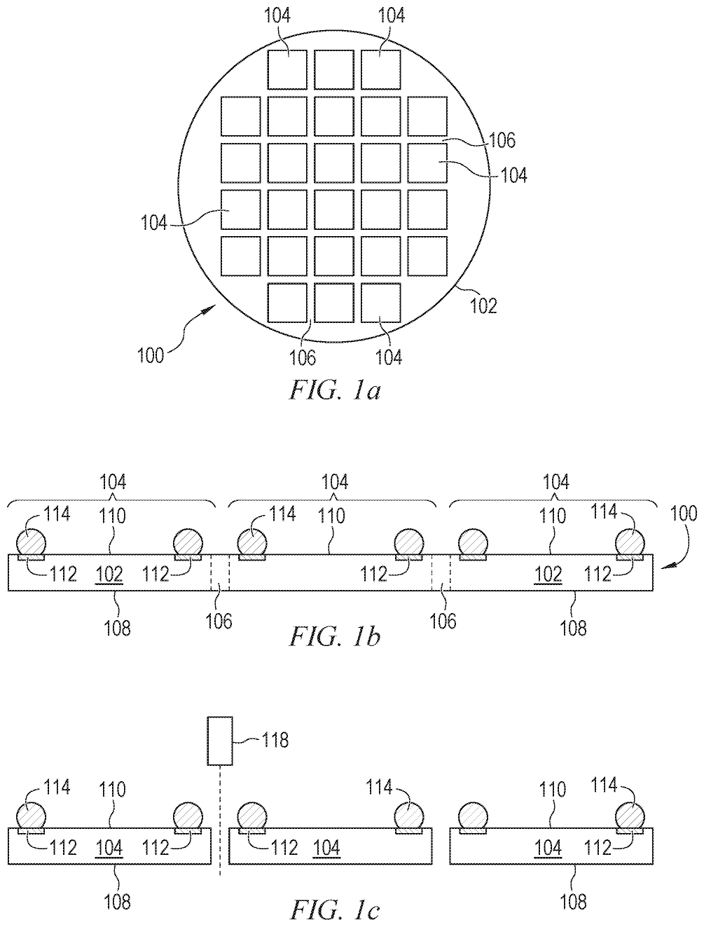

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesive layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or unit (KGD/KGU) post singulation.

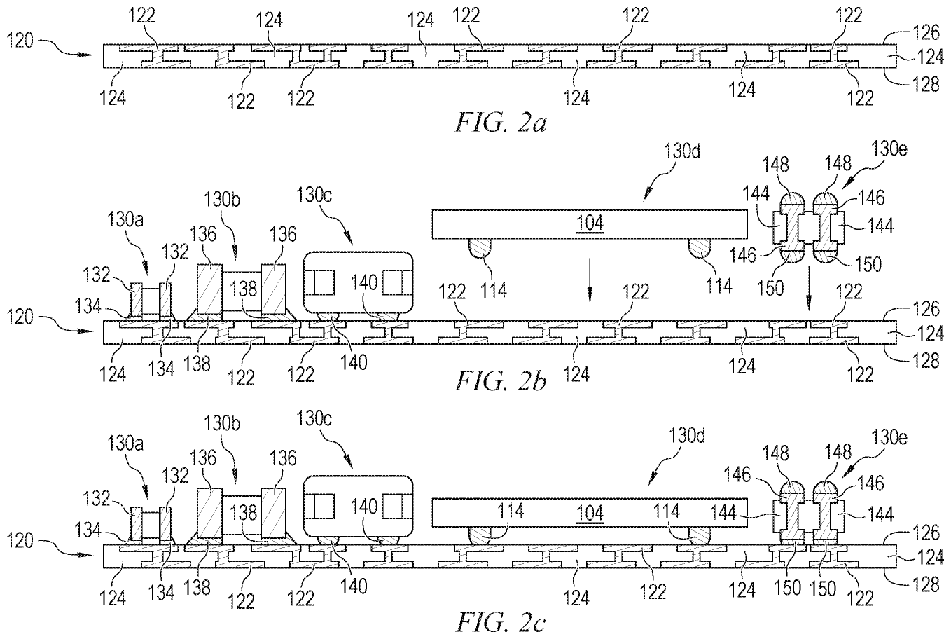

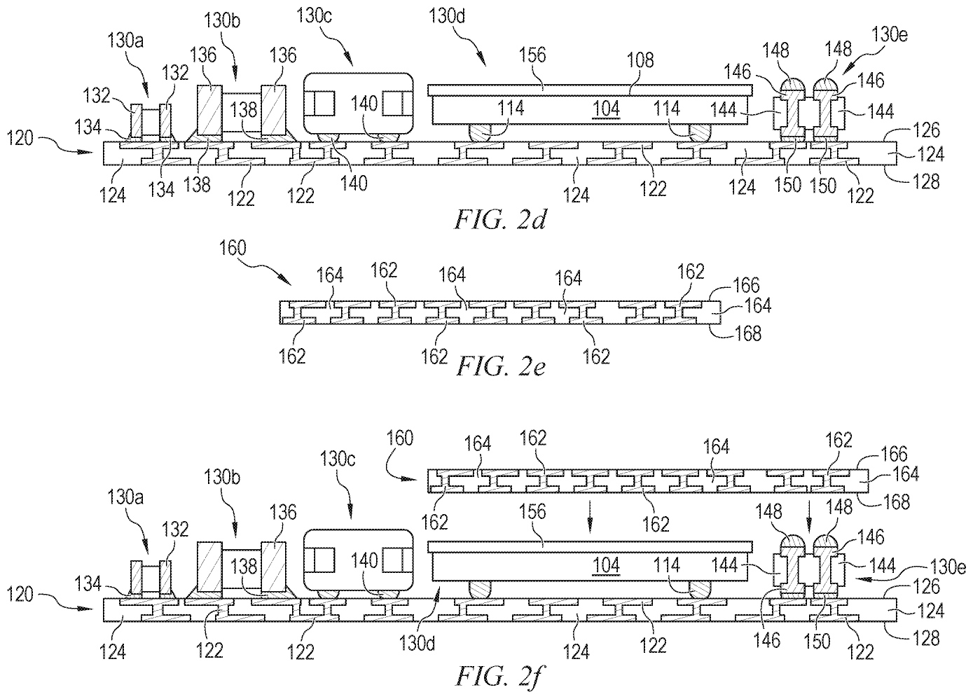

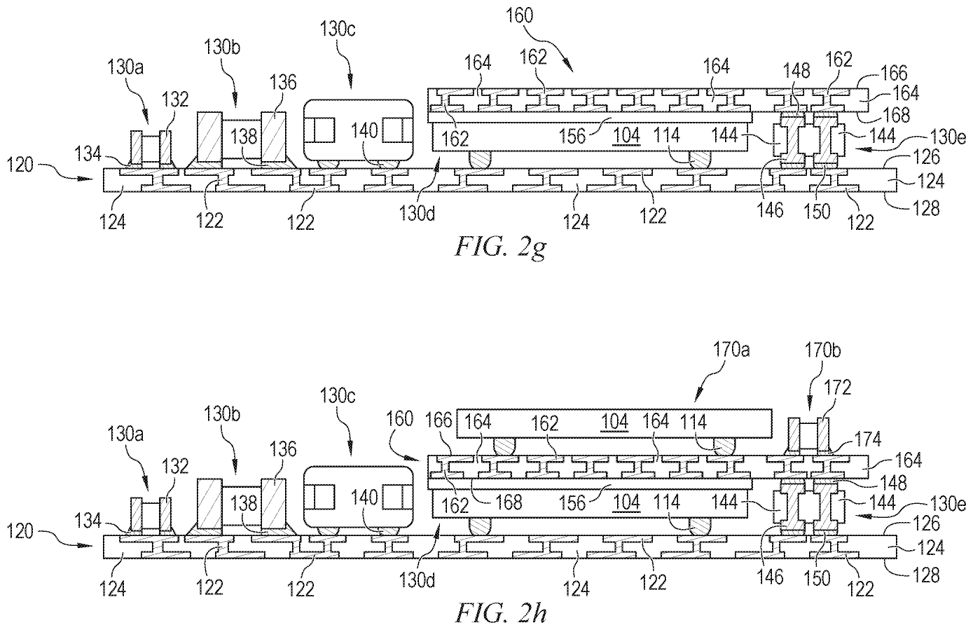

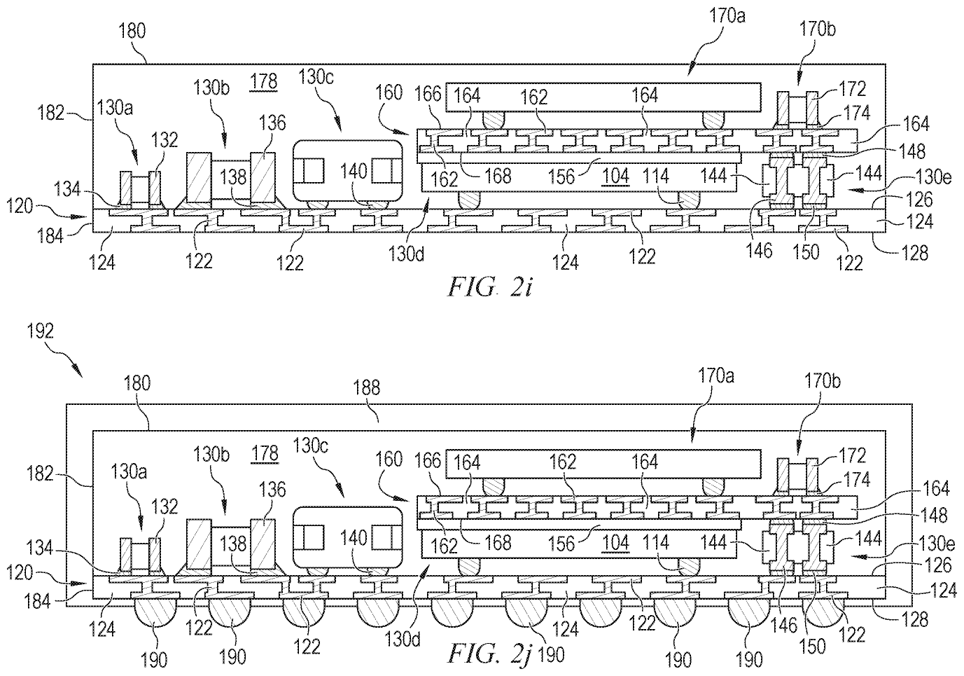

FIGS. 2a-2j illustrate a process of forming a stacked SiP structure having single-sided mold. FIG. 2a shows a cross-sectional view of interconnect substrate or interposer 120 including one or more conductive layers 122 and one or more insulating layers 124. Conductive layers 122 can be one or more layers of Al, Cu, Sn, Ni, Au, Ag, or other suitable electrically conductive material. Conductive layers 122 can be formed using PVD, CVD, electrolytic plating, electroless plating process, or other suitable metal deposition process. Conductive layers 122 provide horizontal electrical interconnect across substrate 120 and vertical electrical interconnect between top surface 126 and bottom surface 128 of substrate 120. Portions of conductive layers 122 can be electrically common or electrically isolated depending on the design and function of semiconductor die 104 and other electrical components. Insulating layers 124 contain one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Insulating layers 124 can be formed using PVD, CVD, printing, lamination, spin coating, spray coating, sintering or thermal oxidation. Insulating layers 124 provide isolation between conductive layers 122. There can be multiple conductive layers like 122 separated by insulating layers 124.

In FIG. 2b, a plurality of electrical components 130a-130e is disposed on surface 126 of interconnect substrate 120 and electrically and mechanically connected to conductive layers 122. Electrical components 130a-130e are each positioned over substrate 120 using a pick and place operation. For example, electrical component 130a can be a discrete electrical device, or IPD, such as a diode, transistor, resistor, capacitor, and inductor, with terminals 132 disposed on surface 126 of interconnect substrate 120 and electrically and mechanically connected to conductive layers 122 with solder or conductive paste 134. Electrical component 130b can be a discrete electrical device, or IPD, such as a diode, transistor, resistor, capacitor, and inductor, with terminals 136 disposed on surface 126 of interconnect substrate 120 and electrically and mechanically connected to conductive layers 122 with solder or conductive paste 138. Electrical component 130c can be a discrete electrical device, or IPD, such as a diode, transistor, resistor, capacitor, and inductor, disposed on surface 126 of interconnect substrate 120 and electrically and mechanically connected to conductive layers 122 with bumps 140. Electrical component 130d can be similar to semiconductor die 104 from FIG. 1c with bumps 114 oriented toward surface 126 of substrate 120. Electrical component 130e can be a discrete electrical device, or IPD, such as a diode, transistor, resistor, capacitor, and inductor, or a semiconductor die similar to die 104. In one embodiment, electrical component 130e is an e-bar interconnect structure with base material 144 and conductive vias 146 formed through the base material and bumps 148 formed over the conductive vias. Electrical component 130e is disposed on surface 126 of interconnect substrate 120 and electrically and mechanically connected to conductive layers 122 with bumps, solder, or conductive paste 150. Alternatively, electrical components 130a-130e can include other semiconductor die, semiconductor packages, surface mount devices, discrete electrical devices, interconnect structures, or IPDs.

Electrical components 130a-130e are brought into contact with surface 126 of substrate 120 and bonded to conductive layer 122. FIG. 2c illustrates electrical components 130a-130e electrically and mechanically connected to conductive layers 122 of substrate 120.

In FIG. 2d, an adhesive 156, such as epoxy resin, is deposited on back surface 108 of electrical component 130d.

FIG. 2e shows a cross-sectional view of interconnect substrate or interposer 160 including one or more conductive layers 162 and one or more insulating layers 164. Conductive layers 162 can be one or more layers of Al, Cu, Sn, Ni, Au, Ag, or other suitable electrically conductive material. Conductive layers 162 can be formed using PVD, CVD, electrolytic plating, electroless plating process, or other suitable metal deposition process. Conductive layers 162 provide horizontal electrical interconnect across interposer 160 and vertical electrical interconnect between top surface 166 and bottom surface 168 of interposer 160. Portions of conductive layers 162 can be electrically common or electrically isolated depending on the design and function of semiconductor die 104 and other electrical components. Insulating layers 164 contain one or more layers of SiO2, Si3N4, SiON, Ta2O5, Al2O3, solder resist, polyimide, BCB, PBO, and other material having similar insulating and structural properties. Insulating layers 164 can be formed using PVD, CVD, printing, lamination, spin coating, spray coating, sintering or thermal oxidation. Insulating layers 164 provide isolation between conductive layers 162. There can be multiple conductive layers like 162 separated by insulating layers 164.

In FIG. 2f, interposer 160 is positioned over electrical components 130d-130e using a pick and place operation with surface 168 oriented toward the electrical components. Surface 168 of interposer 160 is brought into contact with electrical components 130d and 130e and bonded to adhesive layer 156. Bumps 148 are reflowed to make electrical and mechanical connection between conductive layers 162 of interposer 160 and e-bar type electrical component 130e. FIG. 2g illustrates interposer 160 electrically and mechanically connected to electrical components 130d-130e.

In FIG. 2h, a plurality of electrical components 170a-170b is disposed on surface 166 of interposer 160 and electrically and mechanically connected to conductive layers 162, similar to FIGS. 2b-2c. For example, electrical component 170a can be made similar to semiconductor die 104 from FIG. 1c with bumps 114 oriented toward surface 166 of interposer 160. Electrical component 170a may have a different electrical function from electrical component 130d and/or semiconductor die 104. Bumps 114 are reflowed to make electrical and mechanical connection to conductive layers 162. Electrical component 170b can be a discrete electrical device, or IPD, such as a diode, transistor, resistor, capacitor, and inductor, with terminals 172 disposed on surface 166 of interposer 160 and electrically and mechanically connected to conductive layers 162 with solder or conductive paste 174. Alternatively, electrical components 170a-170b can include other semiconductor die, semiconductor packages, surface mount devices, discrete electrical devices, interconnect structures, or IPDs.

In another embodiment, electrical components 170a-170b are disposed on interposer 160 prior to mounting interposer 160 to electrical components 130d-130e.

In FIG. 2i, an encapsulant or molding compound 178 is deposited over and around electrical components 130a-130e, electrical components 170a-170b, interconnect substrate 120, and interposer 160 using a paste printing, compressive molding, transfer molding, liquid encapsulant molding, vacuum lamination, spin coating, or other suitable applicator. Encapsulant 178 can be polymer composite material, such as epoxy resin with filler, epoxy acrylate with filler, or polymer with proper filler. Encapsulant 178 is non-conductive, provides structural support, and environmentally protects the semiconductor device from external elements and contaminants.

Electrical components 130a-130e and 170a-170b may contain IPDs that are susceptible to or generate EMI, RFI, harmonic distortion, and inter-device interference. For example, the IPDs contained within electrical components 130a-130e and 170a-170b provide the electrical characteristics needed for high-frequency applications, such as resonators, high-pass filters, low-pass filters, band-pass filters, symmetric Hi-Q resonant transformers, and tuning capacitors. In another embodiment, electrical components 130a-130e and 170a-170b contain digital circuits switching at a high frequency, which could interfere with the operation of IPDs in SiP module 192 or other IPD in proximity thereto.

To address EMI, RFI, harmonic distortion, and inter-device interference, shielding material 188 is deposited over surfaces 180 and 182 of encapsulant 178, as well as surface 184 of interconnect substrate 120, as shown in FIG. 2j. Electromagnetic shielding material 188 can be one or more layers of Al, Cu, Sn, Ni, Au, Ag, or other suitable conductive material. Alternatively, electromagnetic shielding material 188 can be carbonyl iron, stainless steel, nickel silver, low-carbon steel, silicon-iron steel, foil, conductive resin, carbon-black, aluminum flake, and other metals and composites capable of reducing or inhibiting the effects of EMI, RFI, and other inter-device interference.

An electrically conductive bump material is deposited over conductive layer 122 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 122 using a suitable attachment or bonding process. In one embodiment, the bump material is reflowed by heating the material above its melting point to form balls or bumps 190. In one embodiment, bump 190 is formed over a UBM having a wetting layer, barrier layer, and adhesive layer. Bump 190 can also be compression bonded or thermocompression bonded to conductive layer 122. Bump 190 represents one type of interconnect structure that can be formed over conductive layer 122. The interconnect structure can also use bond wires, conductive paste, stud bump, micro bump, or other electrical interconnect.

Electromagnetic shielding material 188 can also be formed over surface 128 of interconnect substrate 120 around bumps 190.

SiP module 192, as shown in FIG. 2j, contains a plurality of electrical components 130a-130e disposed on substrate 120 and electrical components 170a-170b disposed on interposer 160 and stacked on electrical components 130a-130e. The stacked electrical components and interposer are covered by single-side mold, i.e., encapsulant 178, and shielding material 188 to reduce or inhibit the effects of EMI, RFI, and other inter-device interference. The single-side mold of stacked SiP module 192 requires less manufacturing time and provides a low-cost multifunction system structure.

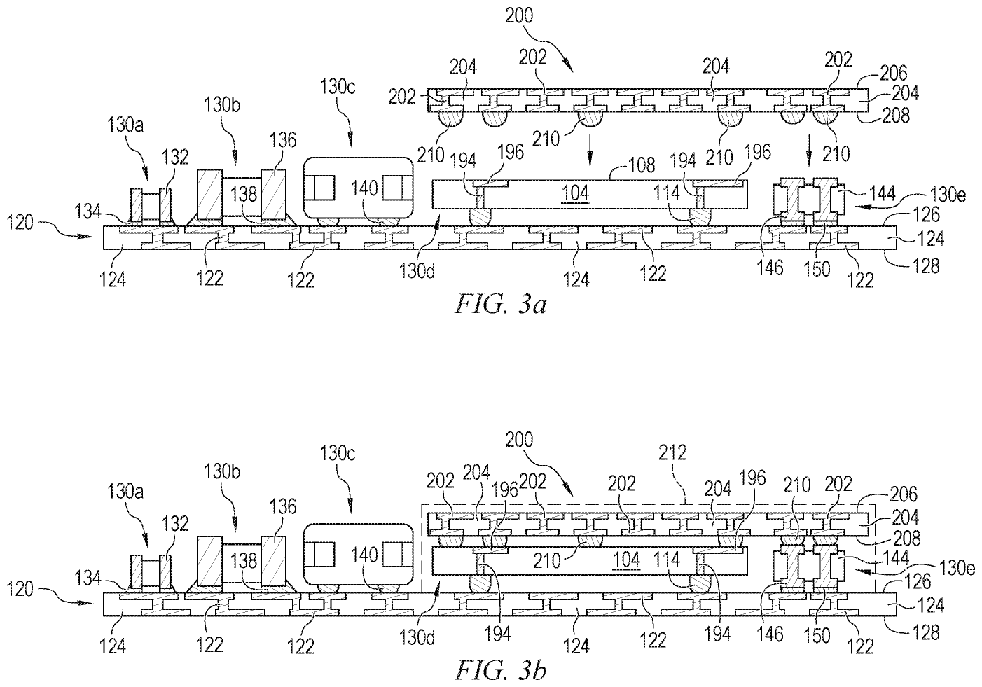

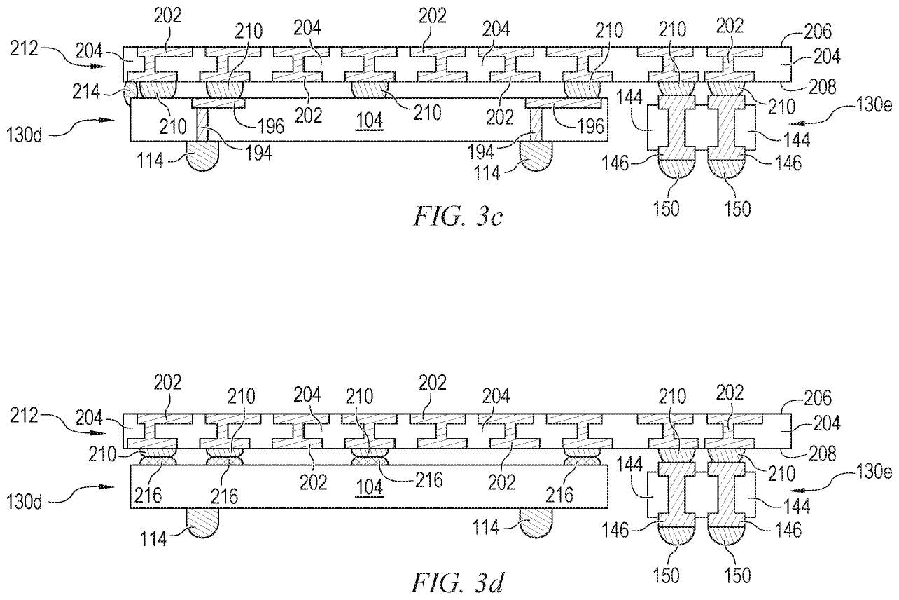

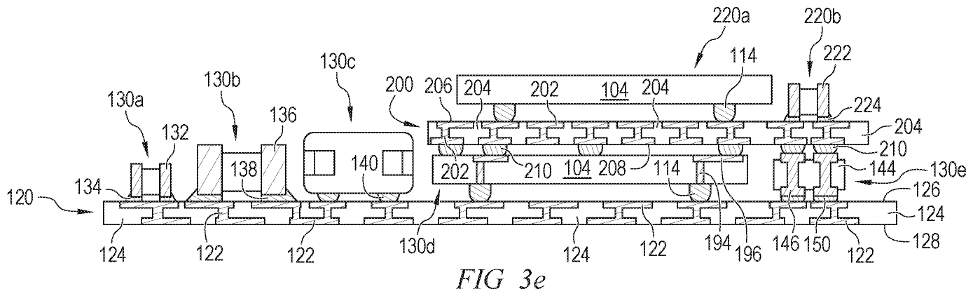

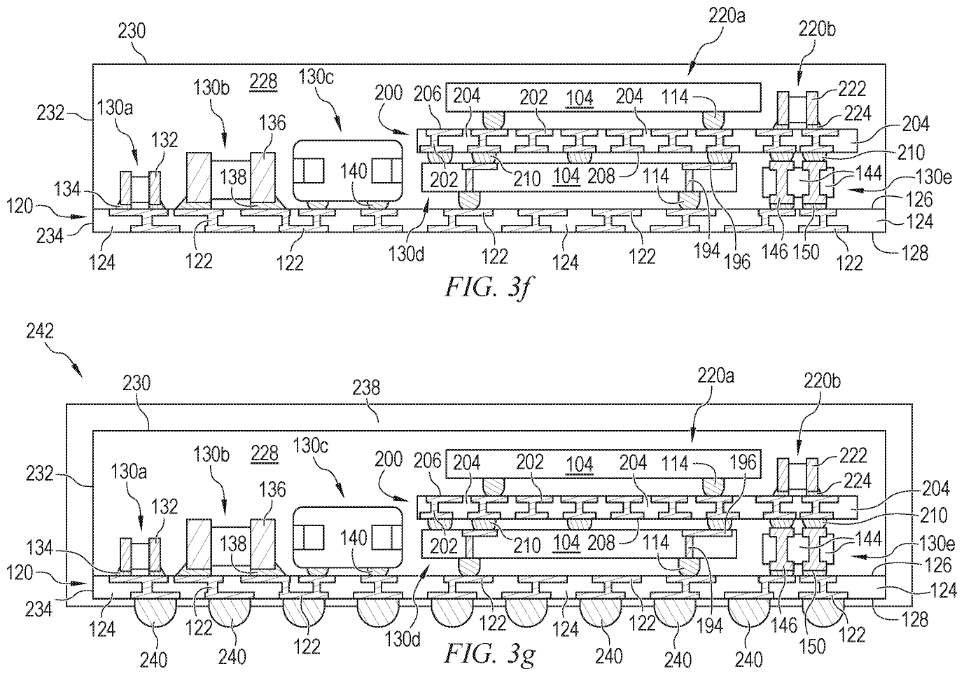

In another embodiment, continuing from FIG. 2c, interconnect substrate or interposer 200 is disposed over electrical components 130d and 130e, as shown in FIG. 3a. In this case, bumps 148 are removed from electrical component 130e. In one embodiment, conductive vias 194 can be formed through electrical component 130d and conductive layer 196 is formed on back surface 108 of electrical component 130d. Alternatively, electrical component 130d has no conductive vias 194 or conductive layer 196, see FIG. 3d.

Interconnect substrate or interposer 200 includes one or more conductive layers 202 and one or more insulating layers 204. Conductive layers 202 can be one or more layers of Al, Cu, Sn, Ni, Au, Ag, or other suitable electrically conductive material. Conductive layers 202 can be formed using PVD, CVD, electrolytic plating, electroless plating process, or other suitable metal deposition process. Conductive layers 202 provide horizontal electrical interconnect across interposer 200 and vertical electrical interconnect between top surface 206 and bottom surface 208 of interposer 200. Portions of conductive layers 202 can be electrically common or electrically isolated depending on the design and function of semiconductor die 104 and other electrical components. Insulating layers 204 contain one or more layers of SiO2, Si3N4, SiON, Ta2O5, Al2O3, solder resist, polyimide, BCB, PBO, and other material having similar insulating and structural properties. Insulating layers 204 can be formed using PVD, CVD, printing, lamination, spin coating, spray coating, sintering or thermal oxidation. Insulating layers 204 provide isolation between conductive layers 202. There can be multiple conductive layers like 202 separated by insulating layers 204. Bumps 210 are formed on surface 208 on conductive layer 202, similar to bumps 190.

Interposer 200 is positioned over electrical components 130d-130e using a pick and place operation with surface 208 oriented toward the electrical components. Surface 208 of interposer 200 is brought into contact with electrical components 130d and 130e and bonded by reflowing bumps 210 to make electrical and mechanical connection to conductive layer 196 of electrical component 130d and conductive vias 146 of e-bar type electrical component 130e. In the case of electrical component 130d having no conductive vias 194 and conductive layer 196, bumps 210 contacting back surface 108 of electrical component 130d are dummy bumps providing structural support for interposer 200. FIG. 3b illustrates interposer 200 electrically and mechanically connected to electrical components 130d-130e.

FIG. 3c illustrates further detail of box 212 from FIG. 3b. An epoxy material 214 is applied to the corner of interposer 200 to hold the interposer in place. FIG. 3c shows the case of electrical component 130d with conductive vias 194 and conductive layer 196. FIG. 3d illustrates another embodiment of box 212 from FIG. 3b. An epoxy material 216 is applied to surface 108 of electrical component 130d to hold interposer 200 in place. FIG. 3d shows the case of electrical component 130d with no conductive vias 194 and conductive layer 196. In FIG. 3d, bumps 210 over electrical component 130d are dummy bumps to provide structural support for interposer 200.

In FIG. 3e, a plurality of electrical components 220a-220b is disposed on surface 206 of interposer 200 and electrically and mechanically connected to conductive layers 202, similar to FIGS. 2b-2c. For example, electrical component 220a can be made similar to semiconductor die 104 from FIG. 1c with bumps 114 oriented toward surface 206 of interposer 200. Electrical component 220a may have a different electrical function from electrical component 130d and/or semiconductor die 104. Bumps 114 are reflowed to make electrical and mechanical connection to conductive layer 202. Electrical component 220b can be a discrete electrical device, or IPD, such as a diode, transistor, resistor, capacitor, and inductor, with terminals 222 disposed on surface 206 of interposer 200 and electrically and mechanically connected to conductive layers 202 with solder or conductive paste 224. Alternatively, electrical components 220a-220b can include other semiconductor die, semiconductor packages, surface mount devices, discrete electrical devices, interconnect structures, or IPDs.

In another embodiment, electrical components 220a-220b are disposed on interposer 200 prior to mounting interposer 200 to electrical components 130d-130e.

In FIG. 3f, an encapsulant or molding compound 228 is deposited over and around electrical components 130a-130e, electrical components 220a-220b, interconnect substrate 120, and interposer 200 using a paste printing, compressive molding, transfer molding, liquid encapsulant molding, vacuum lamination, spin coating, or other suitable applicator. Encapsulant 228 can be polymer composite material, such as epoxy resin with filler, epoxy acrylate with filler, or polymer with proper filler. Encapsulant 228 is non-conductive, provides structural support, and environmentally protects the semiconductor device from external elements and contaminants.

Electrical components 130a-130e and 220a-220b may contain IPDs that are susceptible to or generate EMI, RFI, harmonic distortion, and inter-device interference. For example, the IPDs contained within electrical components 130a-130e and 220a-220b provide the electrical characteristics needed for high-frequency applications, such as resonators, high-pass filters, low-pass filters, band-pass filters, symmetric Hi-Q resonant transformers, and tuning capacitors. In another embodiment, electrical components 130a-130e and 220a-220b contain digital circuits switching at a high frequency, which could interfere with the operation of IPDs in SiP module 242 or other IPD in proximity thereto.

To address EMI, RFI, harmonic distortion, and inter-device interference, shielding material 238 is deposited over surfaces 230 and 232 of encapsulant 228, as well as surface 234 of interconnect substrate 120, as shown in FIG. 3g. Electromagnetic shielding material 238 can be one or more layers of Al, Cu, Sn, Ni, Au, Ag, or other suitable conductive material. Alternatively, electromagnetic shielding material 238 can be carbonyl iron, stainless steel, nickel silver, low-carbon steel, silicon-iron steel, foil, conductive resin, carbon-black, aluminum flake, and other metals and composites capable of reducing or inhibiting the effects of EMI, RFI, and other inter-device interference.

An electrically conductive bump material is deposited over conductive layer 122 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 122 using a suitable attachment or bonding process. In one embodiment, the bump material is reflowed by heating the material above its melting point to form balls or bumps 240. In one embodiment, bump 240 is formed over a UBM having a wetting layer, barrier layer, and adhesive layer. Bump 240 can also be compression bonded or thermocompression bonded to conductive layer 122. Bump 240 represents one type of interconnect structure that can be formed over conductive layer 122. The interconnect structure can also use bond wires, conductive paste, stud bump, micro bump, or other electrical interconnect.

SiP module 242, as shown in FIG. 3g, contains a plurality of electrical components 130a-130e disposed on substrate 120 and electrical components 220a-220b disposed on interposer 200 and stacked on electrical components 130a-130e. The stacked electrical components and interposer are covered by single-side mold, i.e., encapsulant 228, and shielding material 238 to reduce or inhibit the effects of EMI, RFI, and other inter-device interference. The single-side mold of stacked SiP module 242 requires less manufacturing time and provides a low-cost multifunction system structure.

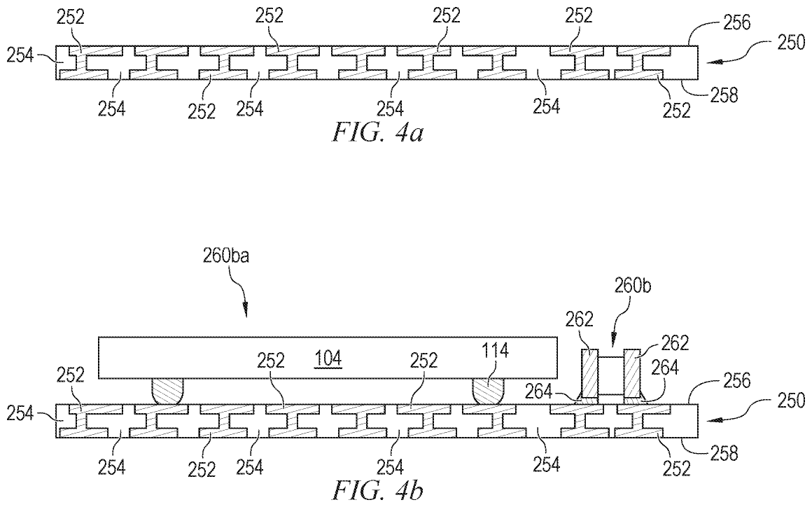

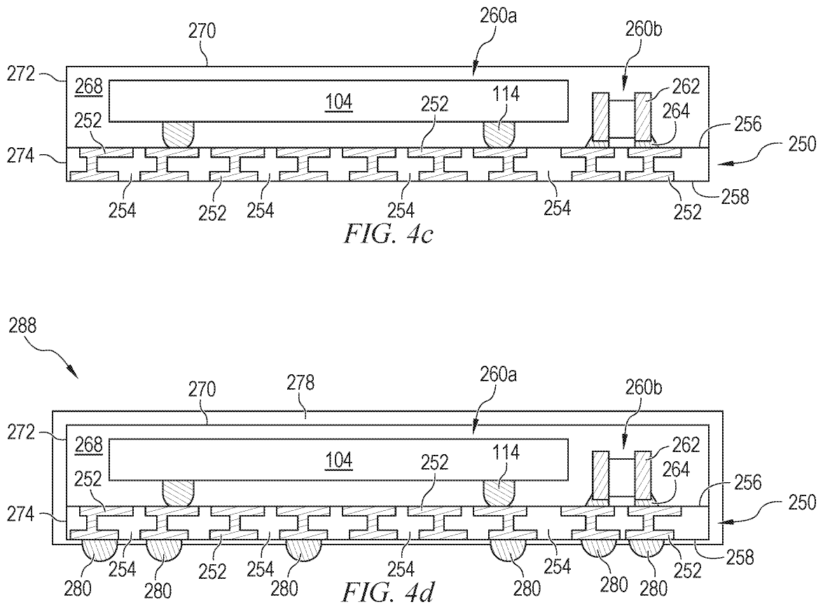

In another embodiment, FIG. 4a shows a cross-sectional view of interconnect substrate or interposer 250 including one or more conductive layers 252 and one or more insulating layers 254. Conductive layers 252 can be one or more layers of Al, Cu, Sn, Ni, Au, Ag, or other suitable electrically conductive material. Conductive layers 252 can be formed using PVD, CVD, electrolytic plating, electroless plating process, or other suitable metal deposition process. Conductive layers 252 provide horizontal electrical interconnect across interposer 250 and vertical electrical interconnect between top surface 256 and bottom surface 258 of interposer 250. Portions of conductive layers 252 can be electrically common or electrically isolated depending on the design and function of semiconductor die 104 and other electrical components. Insulating layers 254 contain one or more layers of SiO2, Si3N4, SiON, Ta2O5, Al2O3, solder resist, polyimide, BCB, PBO, and other material having similar insulating and structural properties. Insulating layers 254 can be formed using PVD, CVD, printing, lamination, spin coating, spray coating, sintering or thermal oxidation. Insulating layers 254 provide isolation between conductive layers 252. There can be multiple conductive layers like 252 separated by insulating layers 254.

In FIG. 4b, a plurality of electrical components 260a-260b is disposed on surface 256 of interposer 250 and electrically and mechanically connected to conductive layers 252, similar to FIGS. 2b-2c. For example, electrical component 260a can be made similar to semiconductor die 104 from FIG. 1c with bumps 114 oriented toward surface 256 of interposer 250. Electrical component 260a may have a different electrical function from electrical component 130d and/or semiconductor die 104. Bumps 114 are reflowed to make electrical and mechanical connection to conductive layer 252. Electrical component 260b can be a discrete electrical device, or IPD, such as a diode, transistor, resistor, capacitor, and inductor, with terminals 262 disposed on surface 256 of interposer 250 and electrically and mechanically connected to conductive layers 252 with solder or conductive paste 264. Alternatively, electrical components 260a-260b can include other semiconductor die, semiconductor packages, surface mount devices, discrete electrical devices, interconnect structures, or IPDs.

In FIG. 4c, an encapsulant or molding compound 268 is deposited over and around electrical components 260a-260b and interposer 250 using a paste printing, compressive molding, transfer molding, liquid encapsulant molding, vacuum lamination, spin coating, or other suitable applicator. Encapsulant 268 can be polymer composite material, such as epoxy resin with filler, epoxy acrylate with filler, or polymer with proper filler. Encapsulant 268 is non-conductive, provides structural support, and environmentally protects the semiconductor device from external elements and contaminants.

Electrical components 260a-260b may contain IPDs that are susceptible to or generate EMI, RFI, harmonic distortion, and inter-device interference. For example, the IPDs contained within electrical components 260a-260b provide the electrical characteristics needed for high-frequency applications, such as resonators, high-pass filters, low-pass filters, band-pass filters, symmetric Hi-Q resonant transformers, and tuning capacitors. In another embodiment, electrical components 260a-260b contain digital circuits switching at a high frequency, which could interfere with the operation of IPDs in SiP module 288 or other IPD in proximity thereto.

To address EMI, RFI, harmonic distortion, and inter-device interference, shielding material 278 is deposited over surfaces 270 and 272 of encapsulant 268, as well as surface 274 of interposer 250, as shown in FIG. 4d. Electromagnetic shielding material 278 can be one or more layers of Al, Cu, Sn, Ni, Au, Ag, or other suitable conductive material. Alternatively, electromagnetic shielding material 278 can be carbonyl iron, stainless steel, nickel silver, low-carbon steel, silicon-iron steel, foil, conductive resin, carbon-black, aluminum flake, and other metals and composites capable of reducing or inhibiting the effects of EMI, RFI, and other inter-device interference.

An electrically conductive bump material is deposited over conductive layer 252 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 252 using a suitable attachment or bonding process. In one embodiment, the bump material is reflowed by heating the material above its melting point to form balls or bumps 280. In one embodiment, bump 280 is formed over a UBM having a wetting layer, barrier layer, and adhesive layer. Bump 280 can also be compression bonded or thermocompression bonded to conductive layer 252. Bump 280 represents one type of interconnect structure that can be formed over conductive layer 252. The interconnect structure can also use bond wires, conductive paste, stud bump, micro bump, or other electrical interconnect.

Electromagnetic shielding material 278 can also be formed over surface 258 of interposer 250 around bumps 280. The assembly shown in FIG. 4d is referenced as shielded SiP module 288.

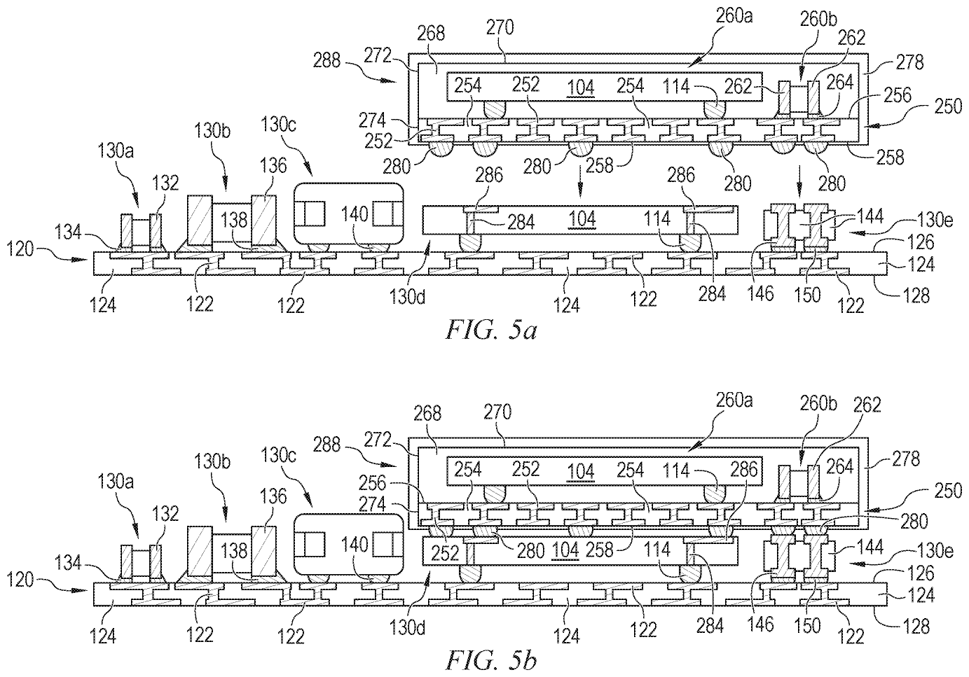

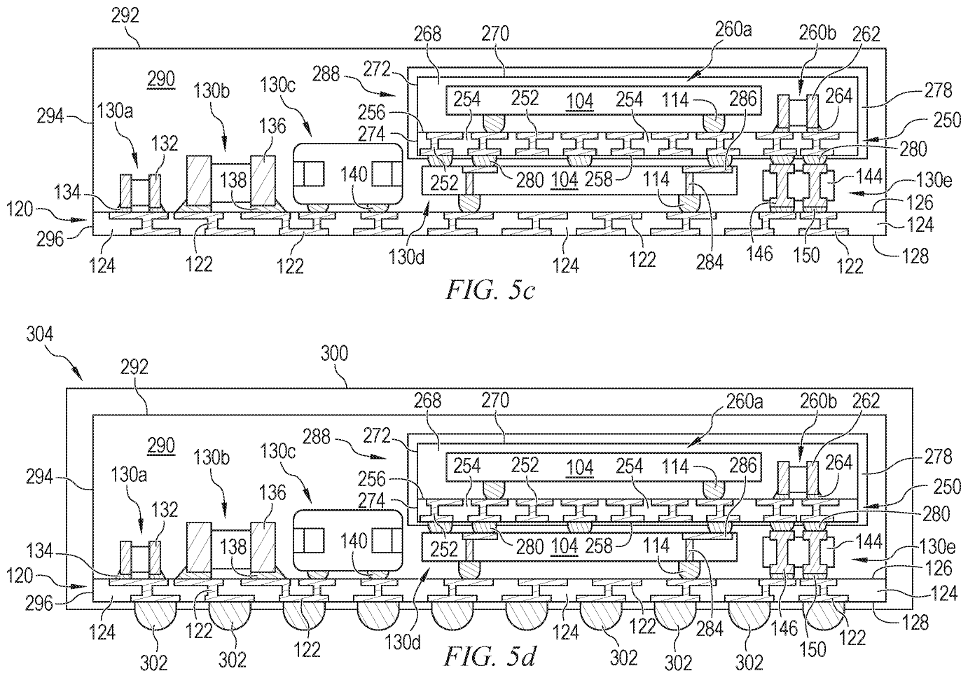

Continuing from FIG. 2c, SiP module 288 is positioned over electrical components 130d-130e using a pick and place operation with surface 258 oriented toward the electrical components, as shown in FIG. 5a. In this case, bumps 148 are removed from electrical component 130e. In one embodiment, conductive vias 284 can be formed through electrical component 130d and conductive layer 286 is formed on back surface 108 of electrical component 130d. Alternatively, electrical component 130d has no conductive vias 284 or conductive layer 286, similar to FIG. 3d.

Surface 258 of interposer 250 is brought into contact with electrical components 130d and 130e and bonded by reflowing bumps 280 to make electrical and mechanical connection to conductive layer 286 of electrical component 130d and conductive vias 146 of electrical component 130e. In the case of electrical component 130d having no conductive vias 284 or conductive layer 286, bumps 280 contacting back surface 108 of electrical component 130d are dummy bumps providing structural support for SiP module 288. FIG. 5b illustrates SiP module 288 electrically and mechanically connected to electrical components 130d-130e.

In FIG. 5c, an encapsulant or molding compound 290 is deposited over and around electrical components 130a-130e, interconnect substrates 120, and SiP module 288 using a paste printing, compressive molding, transfer molding, liquid encapsulant molding, vacuum lamination, spin coating, or other suitable applicator. Encapsulant 290 can be polymer composite material, such as epoxy resin with filler, epoxy acrylate with filler, or polymer with proper filler. Encapsulant 290 is non-conductive, provides structural support, and environmentally protects the semiconductor device from external elements and contaminants.

Electrical components 130a-130e may contain IPDs that are susceptible to or generate EMI, RFI, harmonic distortion, and inter-device interference. For example, the IPDs contained within electrical components 130a-130e provide the electrical characteristics needed for high-frequency applications, such as resonators, high-pass filters, low-pass filters, band-pass filters, symmetric Hi-Q resonant transformers, and tuning capacitors. In another embodiment, electrical components 130a-130e contain digital circuits switching at a high frequency, which could interfere with the operation of IPDs in SiP module 304 or other IPD in proximity thereto.

To address EMI, RFI, harmonic distortion, and inter-device interference, shielding material 300 is deposited over surfaces 292 and 294 of encapsulant 290, as well as surface 296 of interconnect substrate 120, as shown in FIG. 5d. Electromagnetic shielding material 300 can be one or more layers of Al, Cu, Sn, Ni, Au, Ag, or other suitable conductive material. Alternatively, electromagnetic shielding material 300 can be carbonyl iron, stainless steel, nickel silver, low-carbon steel, silicon-iron steel, foil, conductive resin, carbon-black, aluminum flake, and other metals and composites capable of reducing or inhibiting the effects of EMI, RFI, and other inter-device interference. Shielding material 300 further reduces or inhibits the effects of EMI, RFI, and other inter-device interference for SiP module 288.

An electrically conductive bump material is deposited over conductive layer 122 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 122 using a suitable attachment or bonding process. In one embodiment, the bump material is reflowed by heating the material above its melting point to form balls or bumps 302. In one embodiment, bump 302 is formed over a UBM having a wetting layer, barrier layer, and adhesive layer. Bump 302 can also be compression bonded or thermocompression bonded to conductive layer 122. Bump 302 represents one type of interconnect structure that can be formed over conductive layer 122. The interconnect structure can also use bond wires, conductive paste, stud bump, micro bump, or other electrical interconnect.

SiP module 304, as shown in FIG. 5d, contains a plurality of electrical components 130a-130e disposed on substrate 120 and SiP module 288 with electrical components 260a-260b disposed on interposer 250 and stacked on electrical components 130a-130e. The stacked electrical components and interposer are covered by single-side mold, i.e., encapsulant 290, and shielding material 300 to reduce or inhibit the effects of EMI, RFI, and other inter-device interference. The single-side mold of stacked SiP module 304 requires less manufacturing time and provides a low-cost multifunction system structure.

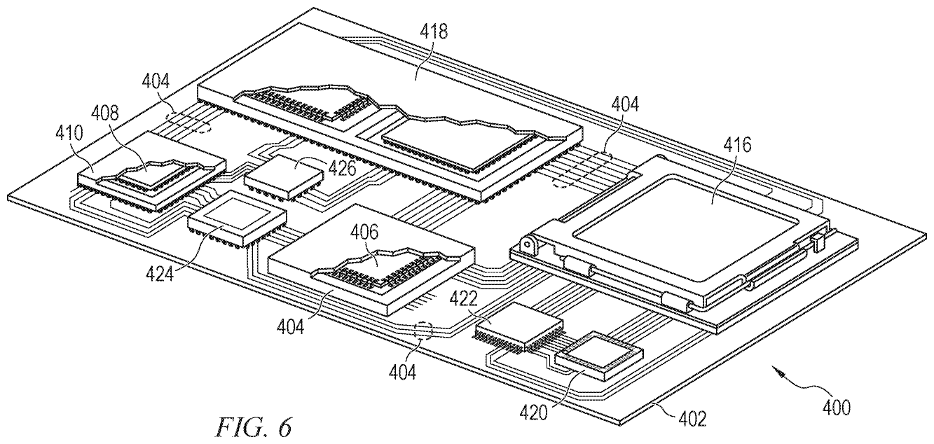

FIG. 6 illustrates electrical device 400 having a chip carrier substrate or PCB 402 with a plurality of semiconductor packages disposed on a surface of PCB 402, including SiP modules 192, 242, and 304. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 6, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and are less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a first substrate;
a plurality of first electrical components disposed over a first surface of the first substrate;
a second substrate;
a plurality of second electrical components disposed over the second substrate, wherein the second substrate is disposed over at least one of the first electrical components;
a first encapsulant deposited over the first substrate, first electrical components, second substrate, and second electrical components; and
a first shielding material disposed over the first encapsulant.

2. The semiconductor device of claim 1, further including:
a second encapsulant deposited over the second substrate and second electrical components; and
a second shielding material disposed over the second encapsulant.

3. The semiconductor device of claim 1, further including an adhesive disposed between the second substrate and the at least one of the first electrical components.

4. The semiconductor device of claim 1, further including a plurality of bumps disposed between the second substrate and the at least one of the first electrical components.

5. The semiconductor device of claim 1, further including an epoxy material disposed between the second substrate and the at least one of the first electrical components.

6. The semiconductor device of claim 1, further including a plurality of bumps formed over a second surface of the first substrate opposite the first surface of the first substrate.

7. A semiconductor device, comprising:
a first substrate;
a first electrical component disposed over a first surface of the first substrate;
a second substrate;
a second electrical component disposed over the second substrate, wherein the second substrate is disposed over the first electrical component; and
a first encapsulant deposited over the first substrate, first electrical component, second substrate, and second electrical component.

8. The semiconductor device of claim 7, further including a shielding material disposed over the first encapsulant.

9. The semiconductor device of claim 7, further including:
a second encapsulant deposited over the second substrate and second electrical component; and
a shielding material disposed over the second encapsulant.

10. The semiconductor device of claim 7, further including an adhesive disposed between the second substrate and the first electrical component.

11. The semiconductor device of claim 7, further including a plurality of bumps disposed between the second substrate and the first electrical component.

12. The semiconductor device of claim 7, further including an epoxy material disposed between the second substrate and the first electrical component.

13. The semiconductor device of claim 7, further including a plurality of bumps formed over a second surface of the first substrate opposite the first surface of the first substrate.

14. A method of making a semiconductor device, comprising:
providing a first substrate;
disposing a plurality of first electrical components over a first surface of the first substrate;
providing a second substrate;
disposing a plurality of second electrical components over the second substrate, wherein the second substrate is disposed over at least one of the first electrical components;
depositing a first encapsulant over the first substrate, first electrical components, second substrate, and second electrical components; and
disposing a first shielding material over the first encapsulant.

15. The method of claim 14, further including:
depositing a second encapsulant over the second substrate and second electrical components; and
disposing a second shielding material over the second encapsulant.

16. The method of claim 14, further including disposing an adhesive between the second substrate and the at least one of the first electrical components.

17. The method of claim 14, further including disposing a plurality of bumps between the second substrate and the at least one of the first electrical components.

18. The method of claim 14, further including disposing an epoxy material between the second substrate and the at least one of the first electrical components.

19. The method of claim 14, further including forming a plurality of bumps over a second surface of the first substrate opposite the first surface of the first substrate.

20. A method of making a semiconductor device, comprising:
providing a first substrate;
disposing a first electrical component over a first surface of the first substrate;
providing a second substrate;
disposing a second electrical component over the second substrate, wherein the second substrate is disposed over the first electrical component; and
depositing a first encapsulant over the first substrate, first electrical component, second substrate, and second electrical component.

21. The method of claim 20, further including disposing a shielding material over the first encapsulant.

22. The method of claim 20, further including:
depositing a second encapsulant over the second substrate and second electrical component; and
disposing a shielding material over the second encapsulant.

23. The method of claim 20, further including disposing an adhesive between the second substrate and the first electrical component.

24. The method of claim 20, further including disposing a plurality of bumps between the second substrate and the first electrical component.

25. The method of claim 20, further including disposing an epoxy material between the second substrate and the first electrical component.
